(19) United States
(12) Patent Application Publication
(10) Pub. No.: US 2007/0096246 A1
(43) Pub. Date: May 3, 2007

(54) Semiconductor device

(75) Inventors: Takahisa Akiba, Tsuruoka (JP); Kunio Watanabe, Sakata (JP); Masahiro Hayashi, Sakata (JP); Tomo Takaso, Chino (JP); Susumu Kenmochi, Tsuruoka (JP)

Correspondence Address: HARNESS, DICKEY & PIERCE, P.L.C., P.O. BOX 828, BLOOMFIELD HILLS, MI, 48303, US

(73) Assignee: Seiko Epson Corporation

(21) Appl. No.: 11/583,095

(22) Filed: Oct. 18, 2006

(30) Foreign Application Priority Data
Oct. 31, 2005 (JP) 2005-316967

(51) Int. Cl. H01L 29/06; H01L 23/58

(52) U.S. Cl. 257/496; 257/618; 257/288

(57) ABSTRACT

A semiconductor device including: a semiconductor layer; a gate insulating layer formed above the semiconductor layer; a gate electrode formed above the gate insulating layer; a channel region formed in the semiconductor layer; a source region and a drain region formed in the semiconductor layer; and an offset insulating layer formed in the semiconductor layer and at least between the channel region and the source region and between the channel region and the drain region, a ratio of a length in a depth direction and a length in a channel length direction of the offset insulating layer being one or less.

Japanese Patent Application No. 2005-316967, filed on Oct. 31, 2005, is hereby incorporated by reference in its entirety.

### BACKGROUND OF THE INVENTION

The present invention relates to a semiconductor device.

In recent years, a portable electronic instrument has been increasingly reduced in weight and size, and research and development have been conducted aiming at reducing the size of an integrated circuit (IC) provided in such an electronic instrument. A plurality of transistors which differ in drive voltage depending on the application are provided in the IC. As a high-voltage-drive transistor, a MOS transistor having an offset structure is used in which the drain region and the channel region are isolated by an insulating layer formed in a semiconductor layer (see JP-A-64-051662, for example).

The high-voltage-drive transistor as mentioned above may have an increased size due to the insulating layer provided in the semiconductor layer, whereby the size of an electric instrument may not be reduced. Accordingly, development of a high-voltage-drive transistor with a reduced size has been demanded.

### SUMMARY

According to one aspect of the invention, there is provided a semiconductor device comprising:

a semiconductor layer;

a gate insulating layer formed above the semiconductor layer;

a gate electrode formed above the gate insulating layer;

a channel region formed in the semiconductor layer;

a source region and a drain region formed in the semiconductor layer; and

an offset insulating layer formed in the semiconductor layer and at least between the channel region and the source region and between the channel region and the drain region,

a ratio of a length in a depth direction and a length in a channel length direction of the offset insulating layer being one or less.

### BRIEF DESCRIPTION OF THE SEVERAL VIEWS OF THE DRAWING

FIG. 1 is a cross-sectional view schematically showing a semiconductor device according to one embodiment of the invention.

### DETAILED DESCRIPTION OF THE EMBODIMENT

The invention may provide a semiconductor device with a reduced size.

(1) According to one embodiment of the invention, there is provided a semiconductor device comprising:

a semiconductor layer;

a gate insulating layer formed above the semiconductor layer;

a gate electrode formed above the gate insulating layer;

a channel region formed in the semiconductor layer;

a source region and a drain region formed in the semiconductor layer; and

an offset insulating layer formed in the semiconductor layer and at least between the channel region and the source region and between the channel region and the drain region,

a ratio of a length in a depth direction and a length in a channel length direction of the offset insulating layer being one or less.

In the semiconductor device according to this embodiment, the offset insulating layer has a shape in which the ratio of the length Y in the depth direction to the length X in the channel length direction (Y/X) is one or less. Therefore, the depths of a well and offset impurity regions including the source region and the drain region can be reduced in comparison with a semiconductor device having an offset insulating layer with the identical distance X but a larger distance Y in the depth direction. As a result, a semiconductor device of a reduced size can be provided. In the invention, the ratio of the length Y in the depth direction to the length X in the channel length direction refers to a value obtained by dividing Y by X.

The semiconductor device according to this embodiment may have the following features.

(2) In this semiconductor device, the offset insulating layer may be formed by a shallow trench isolation (STI) method.

(3) The semiconductor device may further comprise: a first offset impurity region including the source region; and a second offset impurity region including the drain region.

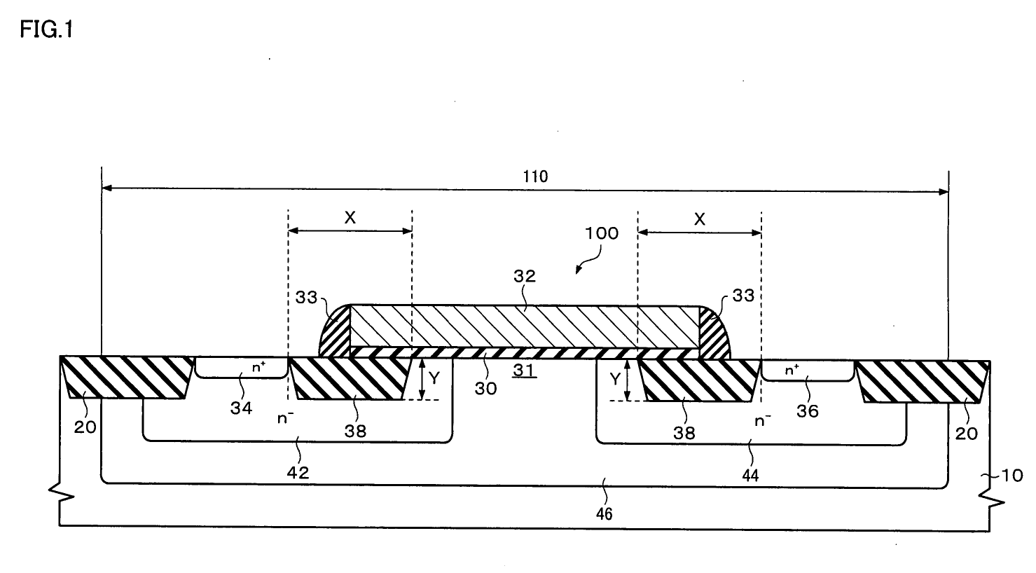

One embodiment of the invention is described below with reference to the drawing. FIG. 1 is a cross-sectional view schematically showing a semiconductor device according to this embodiment. FIG. 1 is a cross-sectional view of a semiconductor device (transistor) 100 along a channel length direction.

The semiconductor device 100 according to this embodiment includes a semiconductor layer 10. The semiconductor layer 10 may be a single crystal silicon substrate or the like. In the semiconductor device 100, a transistor formation region 110 is provided which is defined by an element isolation region 20. The high-voltage-drive transistor 100 is formed in the transistor formation region 110. The transistor 100 includes a gate insulating layer 30, a gate electrode 32, a sidewall insulating layer 33, a channel region 31, a source region 34, a drain region 36, an offset insulating layer 38, offset impurity regions (low-concentration impurity regions) 42 and 44, and a well 46.

The gate insulating layer 30 is formed on a part of the offset insulating layer 38 and the channel region 31. The gate electrode 32 is formed on the gate insulating layer 30. The sidewall insulating layer 33 is formed on the side of the gate electrode 32. The channel region 31 is formed at the top of the well 46 between the source region 34 and the drain region 36 with the offset insulating layer 38 present therebetween. The channel region is a region of the semiconductor layer 10 located below the gate electrode 32 and having the same depth as that of the drain region 36, for example. The source region 34 and the drain region 36 are formed at the top of the well 46 on either side of the gate electrode 32 in the channel length direction. The offset insulating layer 38 is embedded (formed) in the upper surface of the semiconductor layer 10. The offset insulating layer 38 is formed in the semiconductor layer 10 in the transistor formation region 110 in a region other than the channel region 31, the source region 34, and the drain region 36. Specifically, the offset insulating layer 38 is formed in the semiconductor layer 10 in the transistor formation region 110 to avoid the channel region 31, the source region 34, and the drain region 36. The offset insulating layer 38 is an insulating layer formed by an STI method. The cross section of a region of the offset insulating layer 38 positioned between the channel region 31 and at least one of the source region 34 and the drain region 36 has such a shape that the ratio (Y/X) of the distance Y in the depth direction to the distance X from one end to the other in the channel length direction is one or less. The ratio Y/X may be in the range of 0.20 to 0.25, for example.

The offset impurity regions (low-concentration impurity regions) 42 and 44 are formed at the top of the well 46. The low-concentration impurity regions 42 and 44 include the source region 34 and the drain region 36. The low-concentration impurity regions 42 and 44 have the same conductivity type as those of the source region 34 and the drain region 36, and have an impurity concentration lower than those of the source region 34 and the drain region 36. In the semiconductor device according to this embodiment, the low-concentration impurity regions 42 and 44 may include the offset insulating layer 38. The well 46 is formed at the top of the semiconductor layer 10. The well 46 includes the low-concentration impurity regions 42 and 44 and the channel region 31 in the transistor formation region 110.

In the semiconductor device according to this embodiment, when the distance in the longitudinal direction of the channel region 31 is X and the distance in the depth direction (thickness) is Y, the offset insulating layer 38 has such a shape that the value obtained by dividing Y by X is one or less. Therefore, the depths of the well 46 and the offset impurity regions (low-concentration impurity regions) 42 and 44 can be reduced in comparison with a semiconductor device having an offset insulating layer with the identical distance X but a larger distance Y in the depth direction. That is, the depths of the well 46 and the offset impurity regions 42 and 44 can be reduced while maintaining the distance X at a desired level to reduce an electric field between the channel region 31 and the drain region 36. As a result, a semiconductor device which has a reduced size while maintaining reliability can be provided.

The invention is not limited to the above-described embodiments, and various modifications can be made. For example, the invention includes various other configurations substantially the same as the configurations described in the embodiments (in function, method and result, or in objective and result, for example). The invention also includes a configuration in which an unsubstantial portion in the described embodiments is replaced. The invention also includes a configuration having the same effects as the configurations described in the embodiments, or a configuration able to achieve the same objective. Further, the invention includes a configuration in which a publicly known technique is added to the configurations in the embodiments.

Although only some embodiments of the invention have been described in detail above, those skilled in the art will readily appreciate that many modifications are possible in the embodiments without materially departing from the novel teachings and advantages of this invention. Accordingly, all such modifications are intended to be included within the scope of the invention.

What is claimed is:

1. A semiconductor device comprising:
a semiconductor layer;
a gate insulating layer formed above the semiconductor layer;
a gate electrode formed above the gate insulating layer;
a channel region formed in the semiconductor layer;
a source region and a drain region formed in the semiconductor layer; and
an offset insulating layer formed in the semiconductor layer and at least between the channel region and the source region and between the channel region and the drain region,
a ratio of a length in a depth direction and a length in a channel length direction of the offset insulating layer being one or less.

2. The semiconductor device as defined in claim 1,
wherein the offset insulating layer is formed by a shallow trench isolation (STI) method.

3. The semiconductor device as defined in claim 1, further comprising:
a first offset impurity region including the source region; and
a second offset impurity region including the drain region.

4. The semiconductor device as defined in claim 1, further comprising:
a first offset impurity region including the source region; and
a second offset impurity region including the drain region,
wherein the offset insulating layer is formed by a shallow trench isolation (STI) method.
